(19) United States
(12) Patent Application Publication
(10) Pub. No.: US 2020/0033432 A1
(43) Pub. Date: Jan. 30, 2020

(54) METHOD AND APPARATUS FOR IDENTIFYING AT LEAST ONE MATERIAL COMPRISED IN A VOXEL

(71) Applicants: Fraunhofer-Gesellschaft zur Förderung der angewandten Forschung e.V., München (DE); Julius-Maximilians-Universität Würzburg, Würzburg (DE)

(72) Inventors: Martin Blaimer, Würzburg (DE); Peter Jakob, Hausen (DE)

(21) Appl. No.: 16/590,019

(22) Filed: Oct. 1, 2019

Related U.S. Application Data
(63) Continuation of application No. PCT/EP2018/058435, filed on Apr. 3, 2018.

(30) Foreign Application Priority Data
Apr. 5, 2017 (EP) 17165079.9

(51) Int. Cl. G01R 33/561; G06T 11/00; G01R 33/30; G01R 33/24; G06F 17/14

(52) U.S. Cl. CPC G01R 33/5614; G06T 11/008; G06F 17/14; G01R 33/24; G01R 33/307

(57) ABSTRACT

A method for identifying material in a voxel comprises reading in first and second signal trains, each representing magnetization values determined after exposing the material to predefined radio-frequency pulses. The radio-frequency pulses differ before or during measuring the first signal train in at least one parameter from the radio-frequency pulses before or during measuring the second signal train. The method comprises performing a time-domain-frequency-domain transformation (ILFT) to obtain first and second transformation values. The first transformation value represents a frequency domain signal resulting from the time-domain-frequency-domain transformation on the basis of at least the first signal train. The second transformation value represents a frequency domain signal resulting from the time-domain-frequency-domain transformation on the basis of at least the second signal train. The method comprises specifying the material using the first and second transformation values, or values derived from the first and/or second transformation value.

### BACKGROUND

The present invention concerns a method and an apparatus for identifying at least one material comprised in a voxel according to the independent claims. This method can be used for medical MRI or material analysis purposes.

Magnetic resonance (MR) has become a very powerful tool for biomedical diagnosis and material testing. This can be attributed to the fact, that each material (e.g. biological tissue type or synthetic material) has unique relaxation time constants T₁ and T₂, also known as longitudinal and transverse relaxation times respectively. When there are multiple materials in a voxel, T₁ and T₂ relaxation time distributions (i.e. spectra) can be obtained independently with two measurements, e.g. using an inversion-recovery (IR) FLASH sequence for generating a T₁ spectrum or a Carr-Purcell-Meiboom-Gill (CPMG) sequence (or generating a T₂ spectrum.

However, a correlation between the T₁ and T₂ values is not possible in that way. In other words, when there are multiple peaks in the spectra it is not possible to determine which T₂-value correlates to which T₁-value or conversely, which T₁-value correlates to which T₂-value. Therefore, T₁-/T₂-correlation measurements are highly preferred for a better identification of material or tissue types. In principle, this is possible with the IR-CPMG method but requires significantly longer scan times. For example, typically a plurality of measurements (e.g. N=) with different system setting (e.g. inversion times TI) need to be performed. Each individual measurement takes several seconds and therefore, the overall scan time is on the order of several minutes depending on the desired accuracy.

Biomedical imaging applications typically assume a single material in a voxel when performing T₁- and T₂-measurements. Multi-compartment modeling may be used for simultaneously quantifying the T₁- and T₂-values for a limited number of tissue types that are assumed to be within a voxel. However, this approach works only for specific applications (e.g. myelin mapping in the human brain), requires prior knowledge about the disease and works only for a limited number of compartments.

### SUMMARY

In this context, according to a embodiment of the present invention the present invention provides a method for identifying at least one material comprised in a voxel, the method comprising the following steps:
Reading in at least a first and a second signal train, the first and second signal train each representing magnetization values being determined after the material in the voxel was exposed to predefined radio-frequency pulses wherein the predefined radio-frequency pulses exposed or applied to the material in the voxel before or during measuring the first signal train differs in at least one parameter from the radio-frequency pulses exposed or applied to the material in the voxel before or during measuring the second signal train;
Performing at least a time-domain-frequency-domain transformation in order to obtain a first and a second transformation value, the first transformation value representing a frequency domain spectrum resulting from the time-domain-frequency-domain transformation on the basis of at least the first signal train and the second transformation value representing a frequency domain spectrum resulting from the time-domain-frequency-domain transformation on the basis of at least the second signal train;
or
Performing at least a time-domain-frequency-domain transformation in order to obtain a first and a second transformation value, the first transformation value representing a frequency domain spectrum resulting from the time-domain-frequency-domain transformation on the combination of the first and second signal trains and the second transformation value representing a frequency domain spectrum resulting from a different combination of the first and second signal trains;
and
Specifying the material using the first and second transformation values or values derived from the first and second transformation value, in order to identify the material.

A material can be considered to be a biological tissue, for example from a human, an animal or a plant. Alternatively or additionally the material can also be an object or material which has to be identified in a material analysis. Identifying a material can be considered to be a determination of the type of material or of the molecular composition of the material in the voxel, wherein the voxel defines a predefined volume unit at a predefined location in an object or the body. A radio-frequency pulse can be considered to be a magnetic field, especially an oscillating magnetic field, which is superimposed on or applied to the material of the voxel and which turns a magnetic spin of the material of the voxel into predefined directions. A time-domain-frequency-domain transformation can be considered a mathematical operation in which a signal is transformed from the time domain into the frequency domain. Thus, the signal is acquired in the time domain and is transformed in the frequency domain, which can also be understood as a spectral domain such that the time-domain-frequency-domain transformation can be understood as a time-domain-spectral-domain transformation. For example an inverse Laplace transformation or a Fourier transformation can be considered to be such time-domain-frequency-domain transformations.

In order to perform the invention explained in this description a signal train is measured using radio-frequency excitation pulses for example. Before the signal train, one or more radio-frequency preparation pulse may be applied to produce a pre-defined initial magnetization value of the sample (e.g. inverting the sign of the magnetization).

The present invention is based on the finding that said time-domain-frequency-domain transformation provides a very powerful tool to identify the material on the oasis of the first and second transformation values, which themselves are based on two steady-state-free-precession (SSFP) signal trains (or the combination thereof) which are measured when different radio-frequency pulses are exposed or applied to the material in the voxel. Due to the radio-frequency pulses, which differ in at least one parameter as for example in orientation, duration, or a strength of the oscillating magnetic field (resulting in a pre-defined flip angle), applied to the material in the voxel said transformation provides an efficient way in collecting information which can then be used and processed for the identification of the material of the voxel. The invention thus provides the advantage to identify the material very quickly with the minimum of necessary measurement information in contrast of state-of-the-art and with normal numeric effort.

According to a preferred embodiment of the present invention in the step of reading in, a second signal train is read in, in which the parameter of the radio-frequency preparation pulse exposed to the material in the voxel for measuring the second signal train differs in a amplitude, duration or a orientation from a radio-frequency preparation pulse exposed or applied to the material in the voxel for measuring the first signal train, especially in which the radio-frequency preparation pulse exposed to the material in the voxel for measuring the second signal train produces an inversion of the magnetization of the material. Such an embodiment of the present invention provides the advantage that those parameters can be easily measured respectively adjusted such that the identification of the material can be precisely accomplished with little technical effort. Furthermore, such a modification of the radio-frequency pulses has a significant impact on signals which are used for the identification of the material in the voxel.

Additionally or alternatively the parameter of the radio-frequency excitation pulse train exposed or applied to the material in the voxel for measuring the second signal train differs by the flip-angle of the radio-frequency excitation pulse train applied to the material in the voxel for measuring the first signal train. Such an embodiment of the present invention provides the advantage that those parameters can be easily measured respectively adjusted such that the identification of the material can be precisely accomplished with little technical effort. Furthermore, such a modification of the radio-frequency pulses has a significant impact on signals which are used for the identification of the material in the voxel.

According to a further embodiment of the present invention the step of performing comprises performing a time-domain-frequency-domain transformation of terms obtained by a summation and/or a subtraction of the first and second signal trains in order to obtain the first and second transformation values. Thus, the term used as a input for the transformation can be considered to be a sum or a difference of the first and second signal trains. Such a combination of the first and second signal trains prior to the performance of the transformation provides the advantage of an identification of the materials in the voxel based on analytical calculations.

Very little numerical effort has to be taken, if, according to a further embodiment, the step of performing comprises performing an inverse Laplace Transformation and/or a Fourier Transformation, and/or if the step of performing comprises performing a unidimensional time-domain-frequency-domain transformation. The performance embodiments using such a transformation provides the advantage of performing well known and thus numerically optimized transformation algorithms in order to obtain the first and second transformation values.

According to a further embodiment of the present invention the step of performing comprises at feast determining a local maximum of the first and/or second transformation value, especially determining a value, at which the local maximum of the first and/or second transformation value is obtained. Such an embodiment of the present invention provides the advantage that the determination of a local maximum of the first and/or second transformation value provides information on a time constant for the signal train approaching the steady-state after the material in the voxel is exposed to the radio-frequency excitation pulses and from which the identification of the material or the type of material in the voxel can uniquely be drawn. Thus, the local maximum provides a very strong information on determining a longitudinal relaxation value and a transverse relaxation value, which themselves provides an easy and precise identification of the material in that voxel.

In a further embodiment of the present invention, the step of performing comprises a calculation of a longitudinal relaxation value and a transverse relaxation value on the basis of the first and/or second transformation values, especially on the basis of a value, at which the local maximum of the first and/or second transformation value is obtained. Such an embodiment of the present invention provides the advantage of a precise and rapid identification of the material due to the fact that each material has unique values of longitudinal and transverse relaxation values, respectively a unique correlation of longitudinal and transverse relaxation values.

According to another embodiment of the present invention, the step of performing comprises computing an inverse or pseudoinverse of a matrix comprising information about different flip angles used for the radio-frequency excitation pulses applied to the material of the voxel. Such an embodiment provides the advantage of performing an algorithm which can be accomplished in a compact and numerically easy way such that the identification of the material in the voxel is determined quickly.

A very precise and rapid determination of the material in the voxel can be accomplished according to a further embodiment of the present invention in which the step of specifying comprises identifying the material on the basis of at least one correlation of a longitudinal relaxation value and a transverse relaxation value. The identification of the material can, for example, be performed on the basis of a comparison of the (measured or calculated) correlation of the longitudinal relaxation value and the transverse relaxation value with respect to a pre-defined correlation of longitudinal and transverse relaxation values which are, for example, taken from a lookup table. In this lookup table a specific correlation of the longitudinal relaxation value and the transverse relaxation value can be stored which then provides the basis for identification of the specific material under consideration. Therefore, such an embodiment of the present invention provides the advantage of a rapid and still precise determination of the material in the voxel.

Furthermore, the identification accuracy of the material can still be optimized, if according to a further embodiment of the present invention the step of specifying comprises identifying the material on the basis of a proton density value, being read in or being calculated from the first and/or second transformation values or values derived from the first and/or second transformation value. The proton density value provides further information which can be advantageously used for precise identification and determination of the quantity of the distinct material in the voxel. The proton density value can be read in for example from a specific sensor or be calculated from the values already determined or processed in the steps of the method disclosed herein.

In order to precisely determine the proton density of the material in the voxel, according to a further embodiment of the present invention the step of specifying comprises identifying the material on the basis of signal train values at the start (i.e. at time t=0 after the radio-frequency preparation pulses) and in the steady state of the signal train, the flip angle of the radio-frequency excitation pulses and the longitudinal and transverse relaxation values T₁ and T₂. The usage of such parameters of the present invention provides the advantage that these parameters can be easily measured or adjusted in a sensor device such that the identification of the material can be easily, rapidly and precisely accomplished.

Furthermore, the present invention also provides an apparatus being configured for performing, controlling or executing the steps of an embodiment of the here disclosed method in respective units.

The apparatus can presently be considered as an electrical device which is configured to process sensor signals and, dependency thereof, provide control and/or data signals. The sensor signals can for example be signals of a sensor of a medical device respectively of the sensor which is embedded in a medical device. The sensor signals can be considered the sensor signals of a magnetic resonance sensor. The control, data and/or sensor signals can be considered to be signals which are provided to a control or processing unit which is configured to perform the above-mentioned method in separate instances or subunits. Such subunits can, for example, be configured as signal processors or microcontrollers which are capable of performing mathematical algorithms.

Furthermore, an embodiment of the present invention implemented as a computer program project or computer program with program code provides advantages, wherein the computer program product or the computer program with program code is stored on a machine readable carrier for a storage medium as for example a semiconductor storage, a disk storage or an optical storage. The computer program product or the program with program code can be configured for performing and/or controlling the steps of the method according to a previously described embodiment of the present invention, especially if the program product or program is run on a computer or a respectively configured apparatus.

### BRIEF DESCRIPTION OF THE DRAWINGS

Embodiments of the approach presented here are described and depicted in detail with respect to the following figures and description. Shown is in

FIG. 1 a schematic view of a medical device comprising an apparatus according to an embodiment;

FIG. 2A two sequence diagrams for acquiring two signal trains according to a first embodiment of the present invention;

FIG. 2B a schematic of the three basics steps (depicted in the subfigures I, II and III) for fast T₁-T₂-correlation measurements based on balanced SSFP with and without radio-frequency inversion pulse according to a first embodiment of the present invention;

FIG. 3 a diagram for generation of a correlation T₁-/T₂-spectrum from two T₁* spectra obtained from two balanced SSFP measurements (with and without radio-frequency inversion pulse) according to the first embodiment of the present invention;

FIG. 4A two sequence diagrams for acquiring two signal trains according to a second embodiment of the present invention;

FIG. 4B-D in three subfigures 4B, 4C and 4D results from a Proof-of-Principle measurement according to the second embodiment of the present invention; and

FIG. 5 a flow diagram of a method for identifying at least one material comprised in a voxel according to an embodiment of the present invention.

Same or equal elements are denoted by same or equal reference numerals, wherein a repeated description is omitted due to clarity reasons.

### DESCRIPTION

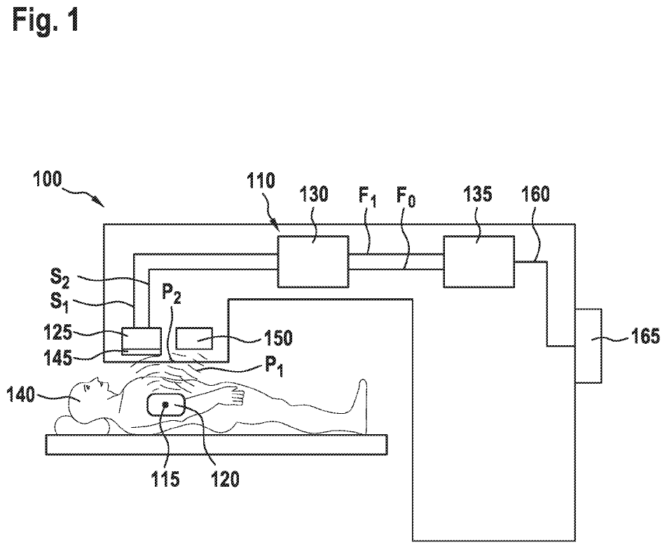

FIG. 1 shows a schematic view of a medical device 100 comprising an apparatus 110 according to an embodiment of the approach presented here. Although the present invention is disclosed in the following description with respect to medical device 100 it is obvious that the invention can be comprised in an apparatus for material analysis, as for example for forensic or material inspection purposes.

The apparatus 110 for identifying at least a material 115 in a voxel 120 comprises an interface or unit 125 for reading in, a unit 130 for performing and a unit 135 for specifying. The voxel 120 can be a volume unit of a predefined size and a predefined location of a human body 140 for example. The unit 125 for reading in is configured for reading in at least a first signal train S1 and a second signal train S2, wherein the first signal train S1 and the second signal train S2 each represent magnetization values of the materials in the voxel (120) which is measured by a (magnet field sensing) sensor 145. The first signal train S1 is specifically measured, after the material 115 in the voxel 120 was exposed to the predefined (first) radio-frequency pulse P1 being sent out from a first magnet emitter 150. The second signal train S2 is specifically measured, after the material 115 in the voxel 120 was exposed to the predefined (second) radio-frequency pulse P2, being sent out from the magnet emitter 150. In this context it is noted that the first radio-frequency pulse P1 differs in at least one parameter from the second radio-frequency pulse P2. For example, the first radio-frequency pulse P1 has a different duration, amplitude or orientation with respect to the magnetic field sent out as the second radio-frequency pulse P2. However as the second radio-frequency pulse P2 is sent out at a time interval after the first radio-frequency pulse P1 it is also possible that the second radio-frequency pulse P2 is sent out by the first magnet emitter 150 with different parameter settings as the sending of the first radio-frequency pulse P1 by the magnet emitter 150.

The apparatus 110 further comprises said unit 130 for performing. In this unit 130 for performing at least a time-domain-frequency-domain transformation is performed in order to obtain a first transformation value F₁ and/or a second transformation value F₀. The first transformation value F₁ represents a frequency domain spectrum resulting from the time-domain-frequency-domain transformation on the basis of at least the first signal train S₁. The second transformation value F₀ represents a frequency domain spectrum resulting from the time-domain-frequency-domain transformation on the basis of at least the second signal train S₂. However, the first transformation value F₁ can be also obtained by said transformation on the basis of a combination of the first S₁ and second S₂ signal trains, for example a sum of the first and second signal trains. The second transformation value F₀ can also be obtained by said transformation on the basis of a combination of the first and second signal trains, for example a difference of the first and second signal trains.

Finally, the apparatus 110 comprises said unit 135 for specifying the material on the basis of the first transformation value F₁ and/or the second transformation value F₀ or values derived from the first transformation value F₁ and/or to second transformation value F₀, in order to identify the material. To be more specific, the unit 135 for specifying is capable of detecting specific molecule or alloy as material in the voxel 120 in order to identify of the material.

The information of the identified specific material can then be output as a material signal 160, which can then be displayed at a respective display unit 165 in order to visualize the identified material in the voxel 120.

The present invention can also be accomplished for on the voxels located at the other positions in the body 140 as the voxel 120 according to FIG. 1 in the human body 140 or for the voxel 120 at the location shown in FIG. 1 repeatedly.

In the subsequently following paragraphs specific embodiments of the present inventions are disclosed in more detail.

Disclosed herein is a time-efficient data acquisition method and corresponding data analysis technique for measuring the correlated magnetic resonance (=MR) relaxation time parameters T₁ and T₂ of at least one material. The MR data acquisition method uses the transient phase of balanced steady-state free procession (bSSFP) measurements being accomplished by the sensor 145 shown in FIG. 1. Especially the combination of only two measurements provides the parameters for calculating the correlated T₁- and T₂-values and the quantity (i.e. relative proton densitiy) of a material in a multi-component sample allowing for a fast and more accurate identification of biological or synthetic materials. In combination with spatial encoding by magnetic field gradients and dedicated image reconstruction algorithms, spatially resolved T₁- and T₂-correlation measurements respectively calculations can be performed enabling patient exams within clinically acceptable measurement times.

In clinical magnetic resonance imaging (=MRI), the quantitative mapping of T₁ and T₂ constants offers several advantages over standard MRI. The quantitative information about T₁ and T₂ may allow for an improved biomedical diagnosis by identifying biomarkers of potential interest. Furthermore, quantitative MRI (qMRI) approaches are of special interest for multi-centric studies because the T₁ and T₂ values should not depend on the particular MR system on which they were acquired. So far, quantitative T₁ and T₂ mapping requires long measurement times and is not applied in clinical routine exams.

A very time-efficient qMRI approach is the inversion-recovery balanced steady-state free precession (IR-bSSFP) technique (also known as IR-TrueFISP) which allows to simultaneously acquiring 2D quantitative information about T₁, T₂ and relative proton density (M₀) within a few seconds per slice. One major limitation of IR-TrueFISP and many other qMRI approaches is the assumption of a single material or tissue type within the volume of interest (also known as voxel). However, typically there exist several material components with different T₁ and T₂ values within one voxel (e.g. fat and water). The acquisition of correlated T₁- and T₂-distributions (i.e. T₁-/T₂-spectra) represents a more accurate way for identifying/characterizing different tissues or material types. The two axes of such a spectrum represent all possible T₁ and T₂ values and each individual peak in the correlated spectrum can be attributed to a unique T₁-/T₂-combination originating from a distinct material.

A widely used technique for measuring correlated T₁-/T₂-spectra is the inversion-recovery (IR) multi-spin-echo (MSE, also known as CPMG) method. However, multiple IR-CPMG measurements with different instrument settings (e.g. different times of inversion, TI) are required for obtaining accurate spectra. Due to the very long measurement times, the IR-CPMG approach is far from being applied in biomedical routine exams.

Instead, the IR-CPMG method is widely used for characterizing biological or synthetic materials such as plastic, oils or biological fluids. However, the long scan times prevent the application of IR-CPMG for inline testing which requires short measurement times to assure high throughput.

In summary, the acquisition of correlated quantitative T₁ and T₂ information allows for an accurate identification of multiple materials within a voxel. However, the long measurement times prevent clinical applications as well as inline material testing of synthetic or biological materials.

Here, an embodiment of the present invention is presented for fast MR relaxography that allows to generate correlated T₁-/T₂ spectra with only two measurements using the bSSFP (a.k.a. TrueFISP) sequence, an approach which is highly lime efficient compared to the state-of-the-art.

In bSSFP, radio-frequency (RF) excitation pulses are repeatedly applied with pre-defined amplitudes (e.g. to achieve a flip angle alpha=40°) and with constant time interval (repetition time, TR) of a few milliseconds (e.g. TR=4 ms) to produce a signal train. After several RF pulses, the signal train approaches a steady state. This phase of approaching the steady state is called transient phase and can be characterized by the following equation:

S_{bssfp}(t)=Sₛₜₛₜ−(Sₛᵢₛᵢ−S_{0,start})·exp(−t/T₁*) [Equation 1]

S_{0,start} characterizes the initial signal at time t=0, Sₛₜₛₜ is the steady-state signal and T₁* represents the time constant for approaching the steady-slate. For a sufficient characterization of the transient phase, the duration of the signal trains should be on the order of 5-T₁.

Assuming a single tissue type (i.e. a material according to the wording in the description of the inventive approach) within the voxel, it has been shown that the material parameters T₁, T₂ and M₀ can be computed from Sₛₜₛₜ, S_{0,start} and T₁*, for example when S_{0,start}=−S₀. Such a initial signal may be achieved by a magnetization preparation (as radio-frequency pulse) using an inversion RF purse. The relationship between the material parameters (T₁, T₂ and M₀) and the measurement parameters derived from the signal train (S₀, Sₛₜₛₜ and T₁*) are given by:

$$\begin{matrix}{T}_{1} = {T}_{1}^{*} \cdot \frac{{S}_{0}}{{S}_{stst}} \cdot cos ( α / 2 ) & [ Equation 2 a ] \\ {T}_{2} = {T}_{1}^{*} \cdot {sin}^{2} ( α / 2 ) \cdot {( 1 - \frac{{S}_{0}}{{S}_{stst}} \cdot cos ( α / 2 ) )}^{- 1} & [ Equation 2 b ] \\ {M}_{0} = \frac{{S}_{0}}{sin ( α / 2 )} & [ Equation 2 c ]\end{matrix}$$

In principle, one may obtain a T₁* spectrum from the measured signal train. To that end, according to one embodiment of the present invention the steady-state signal value is subtracted so that the magnitude of the signal represents a multi-exponential decay. Afterwards, a T₁* spectrum may be obtained by applying the inverse Laplace transform to the resulting signal train. However, it is not possible to compute correlated T₁- and T₂-values from a single T₁* spectrum, because S₀ and Sₛₜₛₜ cannot be obtained from a single spectrum. Instead, the amplitude of the peaks in such a T₁* spectrum is a combination of both S₀ and Sₛₜₛₜ.

To be more specific, the relationship between a set of relaxation decay S(t) data and the relaxation time distribution F(T₁) is known in the slate of the art by the integral equation:

S(tₖ)=∫_{T min}^{T max}F(Tᵢ)·K(tₖ, Tᵢ)dTᵢ

Here, tₖ is the time point for measuring the signal S(tₖ) and T₁ may represent the relaxation time constants T₁, T₂ or T₁*. Formally, this is a Laplace transformation. For the classic Laplace expression, the kernel K(tₖ, Tᵢ) describes an exponential decay and has the form F(tₖ, Tₗ)=exp(−tₓ/Tᵢ). However, other kernels can be used, for example for an inversion recovery experiment for T₁ measurements, the kernel has the form F(tₖ, T₁)−1-2·exp(−tₖ/T₁). The relaxation time distribution F(Tᵢ) can also be called a spectrum or probability distribution of relaxation rate constants Rᵢ=1/Tᵢ.

To obtain the relaxation time distribution F(Tᵢ), the inverse Laplace transform (ILT) is used to solve the above mentioned equation. To that end, this above mentioned equation is typically converted into a system of linear algebraic equations by numerical integration and then solved using a non-negative least-squares fitting algorithm.

However, it has been realized that correlated T₁- and T₂-values can be obtained from only two measurements (N=2) with a bSSFP sequence. In the following, two implementations are described as specific embodiments of the present invention.

### First Embodiment

In the first implementation or embodiment, one measurement is performed with inversion RF preparation pulse and a second measurement is performed without inversion RF preparation pulse prior to the bSSFP sequence. Other sequence parameters are kept identical.

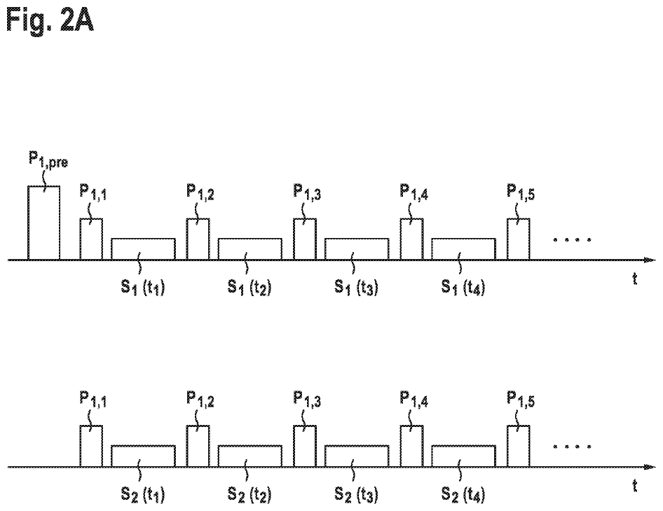

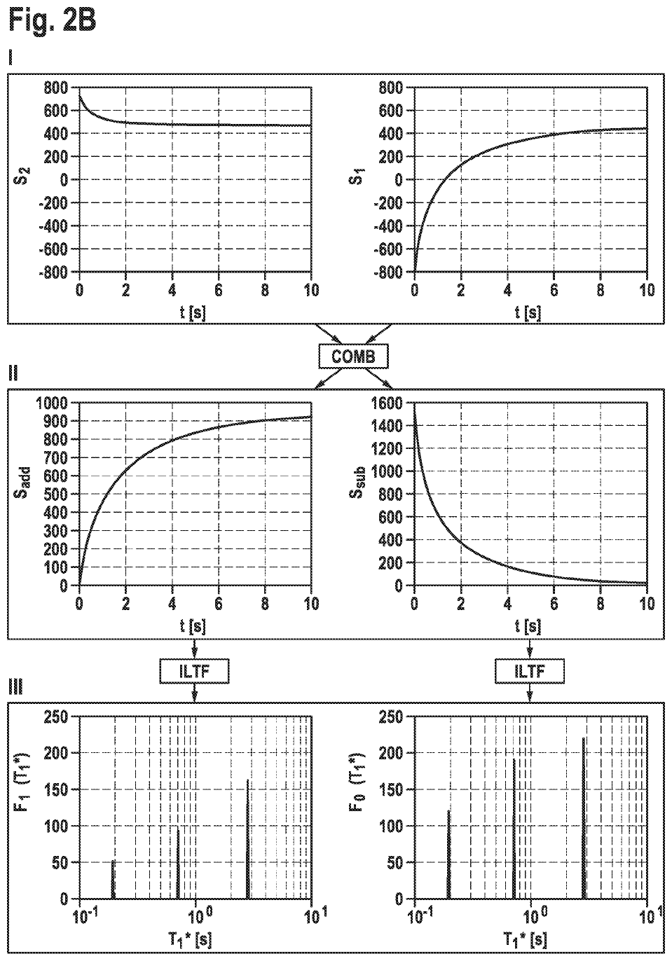

FIG. 2A shows two sequence diagrams for acquiring two signal trains S₁ and S₂ according to the first embodiment. Prior to the first measurement, a radio-frequency preparation pulse P_{1.pre} is applied to invert the magnetization of the spins in the material, which can be seen from the upper diagram of FIG. 2A. Radio-frequency excitation pulses P_{1,n} (with n=1, . . . , N) producing flip angles α_{1,n} are applied to the material to generate the corresponding signals S₁(tₙ). Prior to the second measurement (as shown in the bottom diagram of FIG. 2A), no radio-frequency preparation pulse is applied. The signal train S₂(tₙ) is produced by the same radio-frequency excitation pulses P_{1,n} as in the first measurement.

The signal train for the first measurement with inversion pulse is characterized by

S₁(t)=Sₛₜₛₜ−(Sₛₜₛₜ+S₀)·exp(−t/T₁8) [Equation 3]

The signal train for the second measurement without inversion pulse is characterized by

S₂(t)=Sₛₜₛₜ−(Sₛₜₛₜ−S₀)·exp(−t/T₁*) [Equation 4]

One special aspect of an embodiment of the present invention is the combination of the measured signal trams. The summation of the first measurement (Equation 3) and the second measurement (Equation 4) yields:

S_{sub}(t)=S₂(t)−S₁(t)=2·S₀·exp(−t/T₁*) [Equation 5]

The signal train S_{sub} (t) depends only on Sₛₜₛₜ, T₁* and time t. The subtraction of the first measurement (Equation 3) from the second measurement (Equation 4) yields:

S_{sub}(t)=S₂(t)−S₁(t)=2·S₀·exp(−t/T₁*) [Equation 6]

The signal train S_{sub}(t) depends only on S₀, T₁* and time t. Afterwards, an inverse Laplace transform may be applied to the resulting signal trains to obtain two T₁* spectra: the inverse Laplace transform applied to the signal train S_{add} yields T₁* as a function of Sₛₜₛₜ and the inverse Laplace transform applied to the signal train S_{sub} yields T₁* as a function of S₀. In that way the parameters S₀ and Sₛₜₛₜ can be obtained for each T₁* value allowing to compute the sought-after parameters M₀, T₁ and T₂.

FIG. 2B shows a schematic of the three basics steps (depicted in the subfigures I, II and III) for fast T₁-T₂-correlation measurements based on bSSFP with and without inversion pulse according to a first embodiment of the present invention.

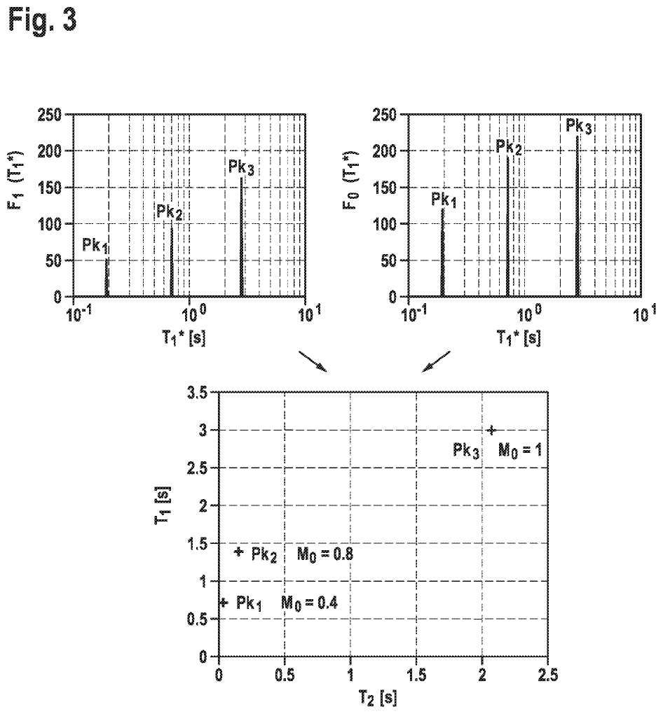

FIG. 3 shows a diagram for generation of a correlation T₁-/T₂-spectrum from two T₁* spectra obtained from two bSSFP measurements (with and without inversion RF pulse) according to the first embodiment of the present invention.

The basic data acquisition and processing steps according to the first embodiment of the present invention are schematically shown in FIGS. 2B and 3 and can be listed as follows:
1) Obtain (or at least read in) signal train S₁ from bSSFP measurement of the transient phase with inversion of the orientation of the material magnetization (see FIG. 2B I, right)
2) Obtain (or at least read in) signal train S₂ from bSSFP measurement of the transient phase without inversion of the orientation of the material magnetization (see FIG. 2B I, left)
3) Combine measured signal trains by performing a Combination COMB by adding measured signal trains in order to obtain the signal train S_{add} (see FIG. 2B II left) and by subtracting measured signal trains in order to obtain signal train S_{sub} (see FIG. 2B II, right) using Equations 5 and 6
4) Compute T₁* distribution as first transformation value F₁=Fₛₜₛₜ=Sₛₜₛₜ(T₁*) for the added signal trains S_{add}, e.g. by inverse Laplace transform ILTF (see FIG. 2B III, left)
5) Compute T₁* distribution as second transformation value F₀=S₀ (T₁*) for subtracted signal trains S_{sub}, e.g. by inverse Laplace transform ILTF (see FIG. 2B III, right)
6) For each T₁* value respectively transformation value, determine S₀(T₁*) from F₀ and Sₛₜₛₜ(T₁*) from F₁=Fₛₜₛₜ and compute the corresponding M₀, T₁ and T₂ values (see FIG. 3) using Equations 2a, 2b and 2c.

In the example in FIG. 2B, three tissue/material components can be identified within in the voxel. These three tissue types respectively material can be obtained by determining the Peaks Pk1, Pk2 and Pk3 in each of the T₁* spectra (which form the first and second transformation values), obtained by transforming the added signal trains S_{add} respectively the subtracted signal trains S_{sub} as depicted in the upper two diagrams of FIG. 3. From the detected peaks Pk1, Pk2 and Pk3 the respective T₁* values can be determined at which the peaks as local maxima occur such that these respective T₁* values can be used to determine the T₁- and T₂-values according to the Equations 2a to 2c as mentioned previously. The correlated T₁-/T₂-values, which are derived from the peaks Pk1, Pk2 and Pk3, are displayed in the lower diagram of FIG. 3. For these correlated T₁-/T₂-values an individual proton density M₀ can also be calculated according to the equation 2c mentioned previously. The determined correlated T₁-/T₂-values and proton density values can then for example be compared with known correlated T₁-/T₂-values and/or proton density values of several materials such that in the case of a predefined level of equality the material in the voxel can be identified as the material, which is allocated the detected correlated T₁-/T₂-value and/or proton density value resulted from the performed steps as mentioned above. The proton density is also used to determine the quantity of a specific material, in other words, M₀ tells us how much of the material is in the voxel.

This identification can be accomplished in a final step of specifying, in which the correlated T₁- and T₂-values for each component (respectively each material or at least one material) in the voxel under consideration can be computed according to Equations 2a-c and represented as a 2D spectrum, which is shown in FIG. 3 at the bottom. The individual material can then for example be identified by comparison of the computed correlated T₁/T₂-values with predefined (expected) correlated T₁-/T₂-values for a distinct material under consideration.

It is relevant to note, that spatial encoding can be applied by switching magnetic field gradients (as known from the state-of-the-art) between the RF-excitation pulses of the bSSFP sequence, e.g. using a Cartesian, a radial or a spiral readout. This allows to produce spatially resolved images at different time points during the transient phase.

### Second Embodiment

In a second implementation or embodiment according to the present invention, two (or more) bSSFP signal trains are acquired where different excitation RF pulses that produce different flip angles α, are employed.

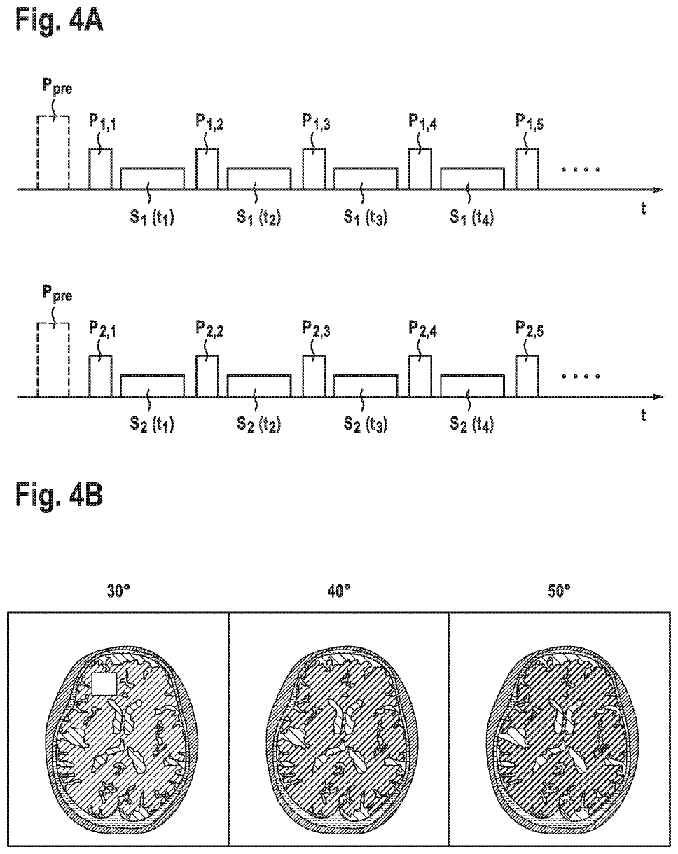

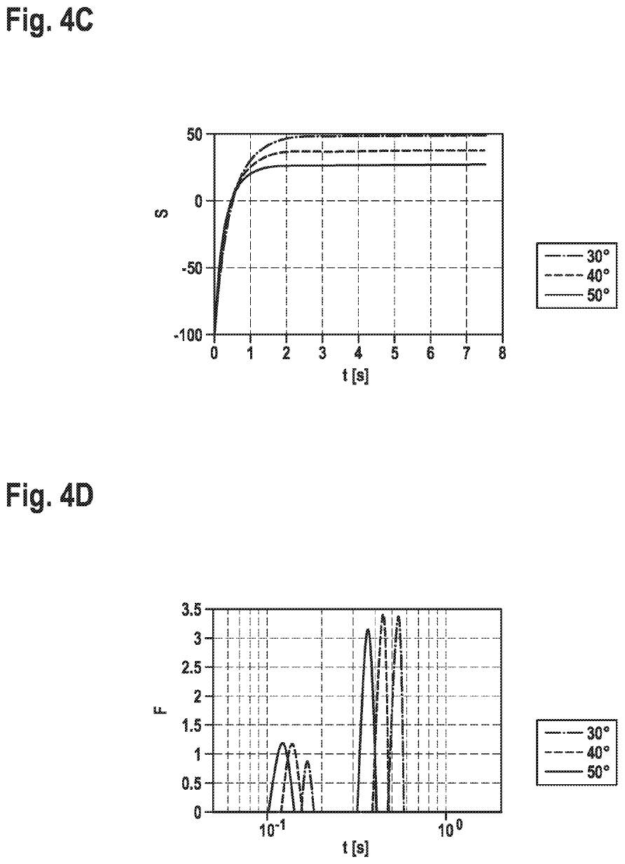

FIG. 4A shows sequence diagrams for acquiring two signal trains S₁ and S₂ according to the second embodiment. In the first measurement (as shown in FIG. 4A in the top diagram), radio-frequency excitation pulses P_{1,n} (with n=1, . . . , Nₚᵤₗₛₑₛ where Nₚᵤₗₛₑₛ represent the number of excitation pulses) producing flip angles α_{1,n} are applied to the material to generate the corresponding signals S₁(tₙ). In the second measurement (shown in the bottom diagram of FIG. 4A), radio-frequency excitation pulses P_{2,n} producing flip angles α_{2,n}≠α_{1,n} are applied to the material to generate the second signal train S₂(tₙ).

A magnetization preparation as for example performed by one or more radio-frequency preparation pulses Pₚᵣₑ (e.g. one inversion pulse or one saturation pulse) may be applied before acquisition of the signal trains. The basic idea is to make use of the fact that T₁* depends on T₁, T₂ and the flip angle α produced by the excitation RF pulses

1/T*₁=1/T₁·cos²(α/2)+1/T₂·sin²(α/2) [Equation 7]

For a series of N measurements (N>1) of different signal trains, this Equation can be rewritten:

1/T*_{1,n}=1/T₁·cos²(αₙ/2)+1/T₂·sin²(αₙ/2) with n=1,2, . . . ,N [Equation 8]

For two bSSFP measurements with different flip angles α₁ and α₂, each material component will have two different T₁* values within the corresponding T₁* spectra. Because T_{1,n}* can be determined from the spectrum (obtained from the corresponding signal train) and αₙ is known from the instrument settings, T₁ and T₂ can be computed, because in this case there are two Equations (T_{1,n}* with n=1,2) and there are two unknowns (T₁ and T₂). In a more general way, Equation 8 may be rewritten in matrix form:

$${r}_{1}^{*} = T \cdot ( \begin{matrix}1 / {T}_{1} \\ 1 / {T}_{2}\end{matrix} ) with T = ( \begin{matrix}{cos}^{2} ( {α}_{1} / 2 ) & {sin}^{2} ( {α}_{1} / 2 ) \\ ⋮ & ⋮ \\ {cos}^{2} ( {α}_{N} / 2 ) & {sin}^{2} ( {α}_{N} / 2 )\end{matrix} ) and {r}_{1}^{*} = ( \begin{matrix}1 / {T}_{1}^{*} ( 1 ) \\ ⋮ \\ 1 / {T}_{1}^{*} ( N )\end{matrix} ) \qquad [ Eq . 9 ]$$

This matrix equation can be solved by computing the generalized inverse (pseudo-inverse, pinv) of the matrix T:

$$( \begin{matrix}1 / {T}_{1} \\ 1 / {T}_{2}\end{matrix} ) = pinv ( T ) \cdot {r}_{1}^{*} \qquad [ Equation 10 ]$$

When T₁, T₂ and α are known, the relative proton density (M₀) can be computed for each peak using the relationship:

$${S}_{stst} = {S}_{0} \cdot \frac{sin α}{1 + cos α + ( 1 - cos α ) ( {T}_{1} / {T}_{2} )} \qquad [ Equation 11 ]$$

Because the peak amplitude F(T₁*) in a T₁* spectrum is given by S₀+Sₛₜₛₜ, S₀ can be obtained from:

$$F = {S}_{0} + {S}_{stst} = {S}_{0} \cdot ( 1 + \frac{sin α}{1 + cos α + ( 1 - cos α ) ( {T}_{1} / {T}_{2} )} ) \qquad [ Equation 12 ]$$

Finally, by combining Equations 2c and 12 the relative proton density of a specific peak is given by:

$${M}_{0} = \frac{F}{sin \frac{α}{2}} \cdot {( 1 + \frac{sin α}{1 + cos α + ( 1 - cos α ) ( {T}_{1} / {T}_{2} )} )}^{- 1} \qquad [ Equation 13 ]$$

Here, F is the measured peak amplitude in one T₁* spectrum and the corresponding T₁ and T₂ values obtained from Equation 10.

The basic steps of the second embodiment of tho present invention can be summarized as follows:
1) Perform (or at least read in) multiple bSSFP measurements of the transient phase with different flip angles αₙ, where n=1, . . . , N and N is the number of measurements (N>1).
2) Generate (or perform a transformation in order to obtain) a T₁* spectrum for each measurement (e.g. by applying the inverse Laplace transform to the measured signal trains) and identify peaks in the spectra
3) Build up matrix T and the vector r₁* using the T_{1,n}* values from the corresponding peaks
4) Solve for T₁ and T₂ according to Equation 10
5) The relative proton density (M₀) may be computed for each peak according to Equation 13.

Analogous to our first implementation, spatial encoding can be applied during the measurements try switching magnetic field gradients between the RF-pulses of the bSSFP sequence, e.g. using a Cartesian, a radial or a spiral readout.

FIG. 4 shows in three subfigures 4B, 4C and 4D results from a Proof-of-Principle measurement according to the second embodiment of the present invention. In-vivo measurements using IR-bSSFP with three different flip angles were performed on a clinical 3 Tesla MR system. A radial readout was used. In total, 1500 radial projections were acquired. 300 images were reconstructed with a sliding-window reconstruction to characterize the transient phase. FIG. 4B shows the final images of the image series with three different flip angles. FIG. 4C shows the signal trains from a small region of interest inside of the white brain matter (indicated by the white square in FIG. 4B). The corresponding T₁* spectra are presented in FIG. 4D. For each flip angle, two components can be identified in the corresponding T₁* spectra. The peaks for component 1 are T_{1,1}*(α=30°)=0.1682 seconds, T_{1,2}*(α=40°)=0.1383 seconds. T_{1,3}*(α=50°)=0.1225 seconds. According to Equations 9 and 10 this corresponds to T₁=0.21 seconds. T₂=0.029 seconds assuming effective flip angles of 0.8·α. The peaks for component 2 are T_{1,1}*(α=30°)=0.523 seconds, T_{1,2}*(α=40°)=0.4358 seconds, T_{1,3}* (α=50°)=0.3632 seconds. According to Equations 9 and 10 this corresponds to T₁=0.71 seconds, T₂=0.078 seconds assuming effective flip angles of 0.8·α. These initial results indicate a fast relaxing species (e.g. myelin) and a slow relaxing species (e.g. intra- and extracellular water pools).

The technical details of embodiments of the present invention can be mentioned as follows
Two (or more) bSSFP signal trains of the transient phase are acquired where at least one sequence parameter is varied (e.g. flip angle of the RF excitation pulses or magnetization preparation pulses such as inversion).
Spatial encoding may be performed by switching magnetic field gradients between the RF pulses to generate a series of images.
A combination of at least two measured signal trains may be performed (e.g. by adding or subtracting the signal trains).
Two (or more) one-dimensional T₁* spectra may be generated (e.g. by computing the inverse Laplace transform of the measured signal trains).
Correlated T₁- and T₂-values and the corresponding relative proton densities (M₀) may be computed from the one-dimensional T₁* spectra.

The here disclosed method(s) allow(s) the quantification of correlated T₁- and T₁-values with only two measurements and represents a highly time efficient approach of identifying a material in a voxel. Compared to state-of-the-art IR-CPMG approach, the approach disclosed here is significantly faster and requires only several seconds scan time to produce correlated T₁- and T₂-values. Furthermore, the method is not based on a particular tissue model and therefore works for a wide range of biomedical applications at different organs.

The application fields of the proposed method are relatively broad and include e.g.
Biomedical application: tissue characterization
Clinical application: improved diagnostics with MR imaging (e.g. Myelin Mapping)
Fast inline material testing and characterization of synthetic, biological or geophysical samples

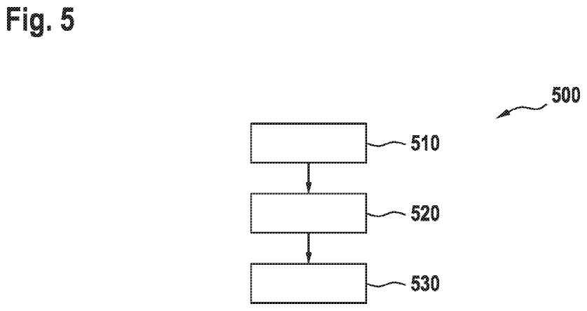

FIG. 5 shows a flow diagram of a method 500 for identifying at least one material comprised in a voxel according to an embodiment of the present invention. The method 500 comprises a step 510 reading in at least a first and a second signal train, the first and second signal trains each representing magnetization values being determined after the material in the voxel was exposed to predefined radio-frequency pulses, wherein the predefined radio-frequency pulses exposed to the material in the voxel before or during measuring the first signal train differs in at least one parameter from the radio-frequency pulses exposed to the material in the voxel before or during measuring the second signal train. Furthermore, the method 500 comprises a step 520 of performing at least a time-domain-frequency-domain transformation in order to obtain a first and a second transformation value, the first transformation value representing a frequency domain signal resulting from the time-domain-frequency-domain transformation on the basis of al least the first signal and the second transformation value representing a frequency domain signal resulting from the time-domain-frequency-domain transformation on the basis of at least the second signal. Finally the method 500 comprises a step 530 of specifying the material using the first and/or second transformation values or values derived from the first and/or second transformation value, in order to identify the material.

1. A method for identifying at least one material (115) comprised in a voxel (120), the method comprising the following steps:
reading in at least a first and a second signal train, the first and second signal train each representing magnetization values being determined after exposing the material in the voxel to predefined radio-frequency pulses, wherein the predefined radio-frequency pulses exposed to the material in the voxel before or during measuring the first signal train differ in at least one parameter from the radio-frequency pulses exposed to the material in the voxel before or during measuring the second signal train, and wherein the first signal train and the second signal train result from steady-state free precession measurements in the transient phase;
performing at least a time-domain-frequency-domain transformation in order to obtain a first and a second transformation value, the first transformation value representing a frequency domain signal resulting from the time-domain-frequency-domain transformation on the basis of at least the first signal train and the second transformation value representing a frequency domain signal resulting from the time-domain-frequency-domain transformation on the basis of at least the second signal train; and
specifying the material using the first and second transformation values or values derived from the first and/or second transformation value, in order to identify the material;
wherein in the step of performing a unidimensional time-domain-frequency-domain transformation is performed.

2. A method according to claim 1, wherein in the step of reading in a second signal train is read in, in which the parameter of the radio-frequency preparation pulse exposed to the material in the voxel before measuring the second signal train differs in an amplitude, a duration and/or an orientation from the radio-frequency preparation pulse exposed to the material in the voxel before measuring the first signal train, and/or wherein the radio-frequency preparation pulse exposed to the material in the voxel before measuring the second signal train produces a magnetization of the material in the voxel with inverted sign as compared to the magnetization produced by radio-frequency preparation pulse exposed to the material in the voxel for measuring the first signal train.

3. A method according to claim 1, wherein in the step of reading in a second signal train is read in, in which the parameter of the radio-frequency excitation pulses exposed to the material in the voxel for measuring the second signal train differs by a flip angle applied to a magnetization of the material in the voxel compared to the flip angles produced by radio-frequency excitation pulses exposed to the material in the voxel for measuring the first signal train.

4. A method according to claim 1, wherein the step of performing comprises performing a time-domain-frequency-domain transformation of terms obtained by a summation and/or a subtraction of the first and second signal train in order to obtain the first and second transformation values.

5. A method according to claim 1, wherein the step of performing comprises performing an inverse Laplace Transformation and/or a Fourier Transformation.

6. A method according to claim 1, wherein the step of performing comprises at least determining a local maximum of the first and/or second transformation value, and/or determining a value at which the local maximum of the first and/or second transformation value is obtained.

7. A method according to claim 1, wherein the step of performing comprises a calculation of a longitudinal relaxation value and a transverse relaxation value on the basis of the first and/or second transformation value, and/or on the basis of a value at which the local maximum of the first and/or second transformation value is obtained.

8. A method according to claim 7, wherein the step of performing comprises computing a inverse or pseudoinverse of a matrix comprising information about different flip angles of the radio-frequency excitation pulses to which the material of the voxel is exposed.

9. A method according to claim 7, wherein the step of specifying comprises identifying the material on the basis of at least one correlation of a longitudinal relaxation value and a transverse relaxation value.

10. A method according to claim 1, wherein the step of specifying comprises identifying the material on the basis of a proton density value, being read in or being calculated from the first and/or second transformation value or values derived from the first and/or second transformation value.

11. A method according to claim 1, wherein the step of specifying comprises identifying the material on the basis of a signal train value in a steady state, a signal train value at the start of the signal train and flip angles of the radio-frequency excitation pulses.

12. An apparatus configured for performing, controlling or executing the steps of a method according to claim 1, including an interface or processor unit adapted for the step of reading in at least the first and second signal train, a processor unit adapted for the step of performing at least a time-domain-frequency-domain transformation, and a processor unit adapted for the step of specifying the material.

13. A computer program configured for performing, controlling or executing the steps of a method according to claim 1, wherein the method is executed on a respectively configured apparatus.

14. A non-transitory, machine readable data storage medium having program code stored thereon, the program code executable on a computer processor to perform a method according to claim 1.
